(19) United States
(12) Patent Application Publication
(10) Pub. No.: US 2005/0213770 A1
(43) Pub. Date: Sep. 29, 2005

(54) Apparatus for generating stereo sound and method for the same

(76) Inventors: Yiou-Wen Cheng, Shu Lin City (TW); Mei-Chun Ku, Tai Chung Hsien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/812,258

(22) Filed: Mar. 29, 2004

(51) Int. Cl. H04R 5/00; H03G 3/00

(52) U.S. Cl. 381/1; 381/63; 381/17

(57) ABSTRACT

An apparatus and method for generating a stereo sound has a direct sound positioner, a reverberation positioner, multiple sound integrators, a left reverberation generator and a right reverberation generator. It uses the direct sound positioner and reverberation positioner to produce the directional effect of sounds and uses the left and right reverberation generators produce the spatial effect of the sounds. Further, it adjusts the ratio of the directional sounds and the reverberation via the integrators to achieve the required sound effects.

### FIELD OF THE INVENTION

The present invention is directed to an apparatus for generating a stereo sound and method for the same, and more particularly, to an apparatus and method that process direct sound and reflected sound separately and process the sounds received by the left and right ears individually to obtain a wider sound extensity.

### BACKGROUND OF THE INVENTION

Conventionally, a virtual sound playing apparatus is used to create a virtual world to make a user feel personally on the scene via sounds. Hence, virtual sound effects should be realistic. In general, the lower the correlation between the sounds received by right and left ears is, the more the user can feel the extensity of sounds.

Reference is made to FIG. 1A. The rectangular space 100 has a sound source 110 disposed therein. When the sound source 110 sends out a sound, the sound will be propagated in all directions. Hence, a user 120 can hear different sounds, including a direct sound 114, which is received by the user directly from the sound source 110, and a reflected sound 112, which is reflected by an obstacle of the space 100 and then received by the user after propagation through an extra distance, called a distance difference 112A. Since a human ear can experience a stereo sound via direct and reflected sounds, the method for producing virtual sound effects is to allow the human ears able to experience and recognize directional sounds (including direct sounds and reflected sounds), synthesize the reverberation and control the timing for combining both of the directional sounds and reverberation.

The human sense of direction of sounds is determined primarily by the obstruction of the head, the diffraction effect and the reflection time difference resulted from the shape of the pinna. Their effects mainly have three categories:
1. interaural intensity differences;
2. interaural time differences; and
3. pinna reflection.

Moreover, the human sense of space and distance via sound is determined primarily by two factors:
1. volume ratio of the reverberation and direct sound; the larger the volume of the reverberation is, the larger the space feels; and
2. time difference between the reverberation and direct sound; the larger the time difference is, the larger the space feels.

The reverberation mentioned above refers to the echo and consonance of the environment after the original sounds are sent out. The sounds gradually die out with time. The method for producing the reverberation is the method for designing the filter. In accord with the features of the reverberation and different delay times, different reverberation filters can be produced. After the convolution of the original sounds with the reverberation filter is performed, the reverberation can be generated.

The Method for designing the reverberation filters has two categories:
1. a finite impulse response (FIR) filter, which is made mostly according to the directly detected reverberation response of the environment and can achieve the most natural effect but has a high calculation complexity; and
2. an infinite impulse response (IIR) filter, which is an all pass filter used for generating the reverberation with infinite impulse response length and has a low calculation complexity, but produces an unnatural reverberation.

Reference is made to FIG. 1B, which illustrates a sound model received by a human ear. The vertical coordinate represents amplitude and the horizontal coordinate represents time. A human ear receiving a sound signal receives the direct sound 160 first, then the early reflected sound 110 and finally the reverberation 180.

Conventionally, the serial calculating structure is used mostly to produce the reverberation and directional sounds. Reference is made to FIGS. 2A and 2B. As shown in the figures, before received by ears of a user 230, the signal of the sound channel 200 will be processed via the directional sound generator 210 first and then via the reverberation generator 220, or processed via the reverberation generator 220 first and then via the directional sound generator 210.

However, this structure has several drawbacks, which are described as follows. First, with reference to FIG. 3, as the number of the input sound channels 300 increases, the number of the directional sound generators 320 and the reverberation generators 310 increases linearly and hence the calculation complexity will also increase. Secondly, with reference to FIG. 4, as the direct sound 114 and the reflected sound 112 overlap, the directional sound and reverberation also overlap and can't be controlled individually. Hence, they will interfere with each other. Since the direction of the direct sound is exactly the same as that of the reflected sound, the difference of the direct and reflected sounds will be ignored and hence the user is not able to experience the realistic extensity.

In U.S. Pat. No. 6,188,796, different reverberation signals use a common reverberation generator, which employs an all pass filter as an IIR filter to produce reverberation with infinite impulse response. Its calculation is simpler, but the correlation of the produced reverberation signals used for left and right ears is higher and the reverberation signals are more unnatural. Hence, the extensity of the reverberation is worse. Further, this patent separates the sounds into three sound channels for parallel processing, which is more complicated.

The present invention overturns the conventional structure. It processes the direct and reflected sounds separately and makes the input sound channels use common reverberation generators to lower the complexity of the structure and keep the flexibility for adjusting and controlling.

### SUMMARY OF THE INVENTION

The present invention is directed to an apparatus for generating a stereo sound and method for the same. It has a parallel structure, including a direct sound positioner, a reverberation positioner, multiple sound integrators, a left reverberation generator, a right reverberation generator and multiple space processors. By separately processing the direct and reflected sounds, the complexity can be lowered and the flexibility for adjusting and controlling can be kept. The calculation complexity does not increase linearly with the number of the input sound channels. Further, all the sound channels use common reverberation generators regardless of the number of input sounds. Hence, the structure of the apparatus can be simplified. Since the direct and reflected sounds are processed separately, the processing methods for them can be designed individually according to the situation of a site or the required effect. Hence, the apparatus can be controlled more easily.

Another feature of the present invention is that the reverberation generators for left and right ears are different. Hence, the correlation of the reverberation signals for the left and right ears can be reduced considerably and the extensity of the reverberation can become broader.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1A is a propagation model of a sound.

FIG. 1B is a sound model received by a human ear.

FIG. 2A is a block diagram of a conventional apparatus for generating sounds;

FIG. 2B is a block diagram of a conventional apparatus for generating sounds;

FIG. 3 is a block diagram of a conventional apparatus having multiple sound channels;

FIG. 4 is a propagation model of a sound, in which the direct and reflected sounds overlap;

FIG. 5 is an embodiment of the present invention;

FIG. 6A is a diagram of a reverberation signal before decorrelation;

FIG. 6B is a diagram of a left reverberation signal after decorrelation;

FIG. 6C is a diagram of a right reverberation signal after decorrelation; and

FIG. 7 is a flowchart of the present invention.

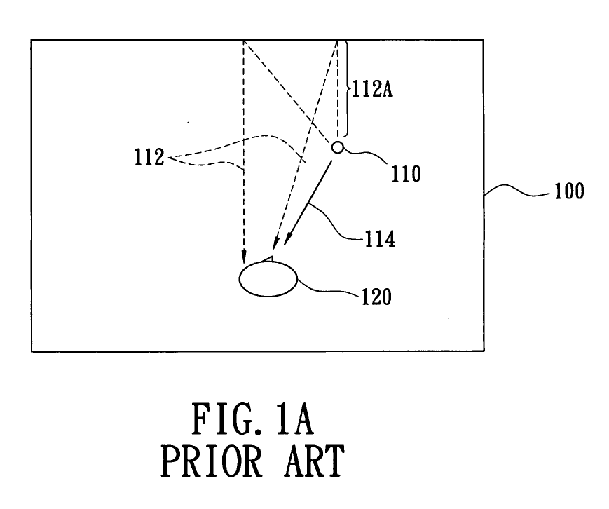

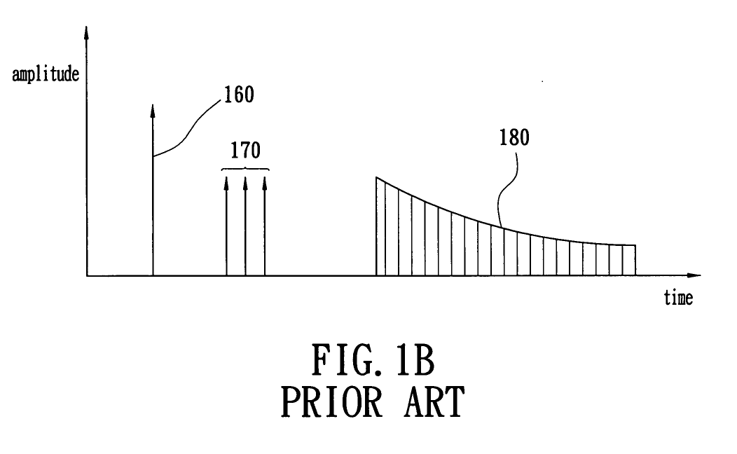

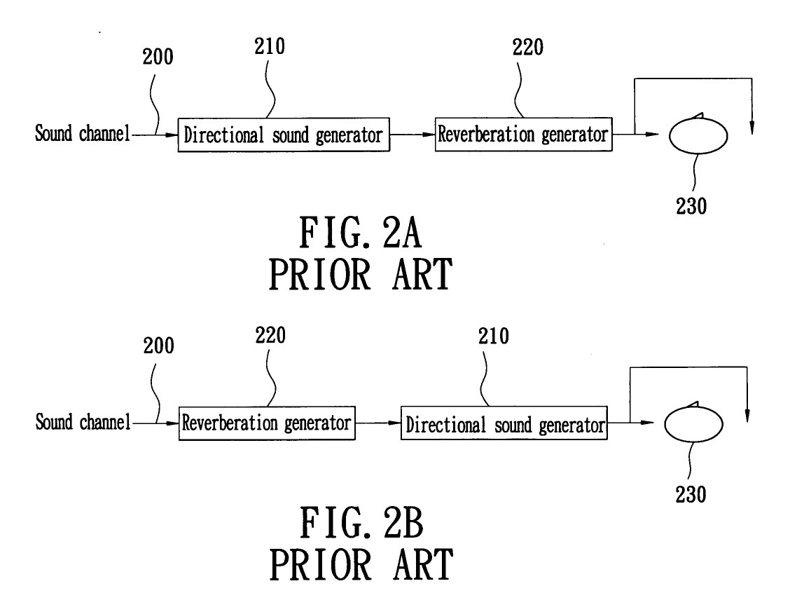

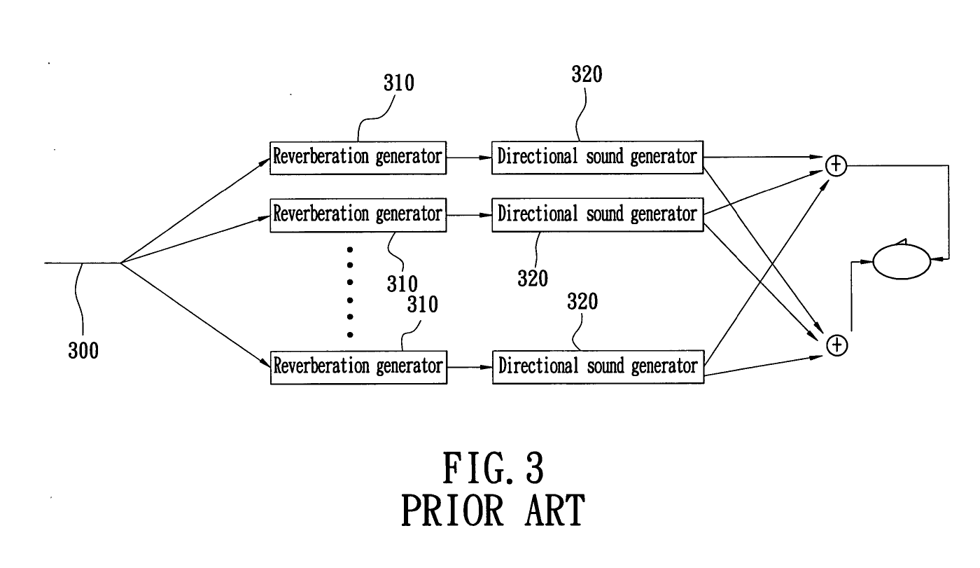

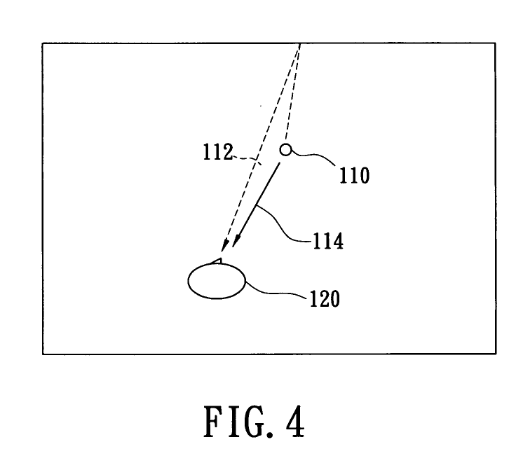

### DETAILED DESCRIPTION

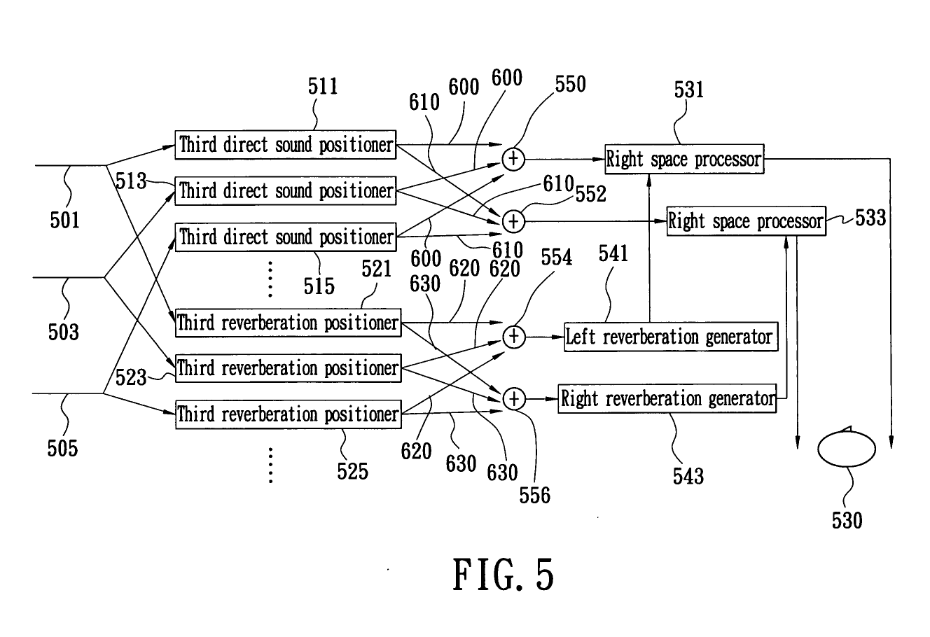

Reference is made to FIG. 5, which is an embodiment of the present invention. As shown in the figure, the first sound channel 501 will be respectively input into the first direct sound positioner 511 and first reverberation positioner 521, which are disposed in parallel. Similarly, the second sound channel 503 will be respectively input into the second direct sound positioner 513 and second reverberation positioner 523 disposed in parallel, and the third sound channel 505 will be respectively input into the third direct sound positioner 515 and third reverberation positioner 525 disposed in parallel. The direct sound positioners 511, 513, 515 and the reverberation positioners 521, 523, 525 are used to generate directional sounds.

Subsequently, the left direct sound signals 600 generated by the direct sound positioners 511, 513, 515 are sent to the first left sound integrator 550 together. Similarly, the right direct sound signals 610 generated by the direct sound positioners 511, 513, 515 are also sent to the first right sound integrator 552, together.

The sound signals from the sound channels 501, 503, 505 are first sent to the reverberation positioners 521, 523, 525 disposed in parallel, respectively. Then, the left reverberation direction signals 620 generated by the reverberation positioners 521, 523, 525 will be sent to the second left sound integrator 554 together. Similarly, the right reverberation direction signals 630 generated by the reverberation positioners 521, 523, 525 will be sent to the second right sound integrator 556 together.

After integrating the input signals, the second left sound integrator 554 will output an integrated reverberation direction signal to a left reverberation generator 541. Then, the reverberation signal output from the left reverberation generator 541 and the integrated direct sound signal output from the first left sound integrator 550 will be sent to the left space processor 531. The left reverberation generator 541 includes a finite impulse response (FIR) filter.

Similarly, after integrating the input signals, the second right sound integrator 556 will output an integrated reverberation direction signal to a right reverberation generator 543. Then, the reverberation signal output from the right reverberation generator 543 and the integrated direct sound signal output from the first right sound integrator 552 will be sent to the right space processor 533. The right reverberation generator 543 includes a finite impulse response (FIR) filter.

The FIR filters of the left reverberation generator 541 and right reverberation generator 543 can be used to decorrelate the left and right sound signals to obtain the required stereo extensity.

Finally, the left space processor 531 will adjust the ratio of the reverberation signal output from the left reverberation generator 541 and the integrated direct sound signal output from the first left sound integrator 550 to provide sounds for a user's left ear while the right space processor 533 will adjust the ratio of the reverberation signal output from the right reverberation generator 543 and the integrated direct sound signal output from the first right sound integrator 552 to provide sounds for the user's right ear. Further, the left space processor 531 and the right space processor 533 are used to adjust the ratio and timing of the two sounds and the mixed volume.

In decorrelation, when the correlation of the sounds input to the left and right ears is high, a user will feel the sounds are monotonous and unreal; in contrast, when the correlation of the sounds is lowered, the user will feel the sounds are full of extensity, as if from outside rather than from the brain. In general, the decorrelating method is to disarrange the phases of the sounds input to the left and right ears.

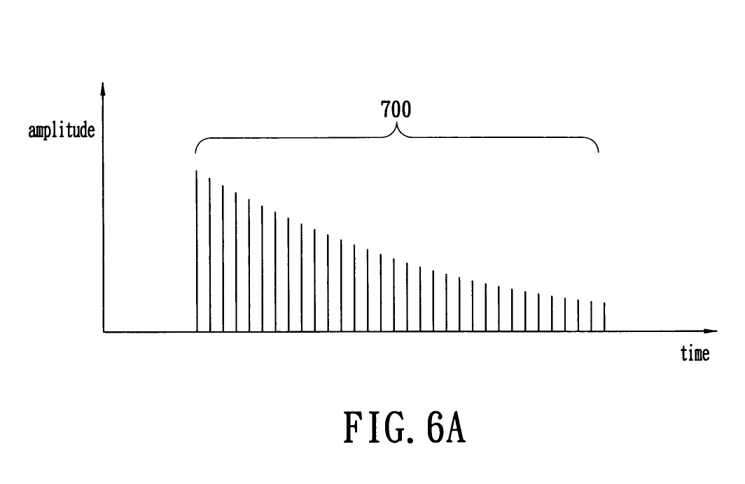

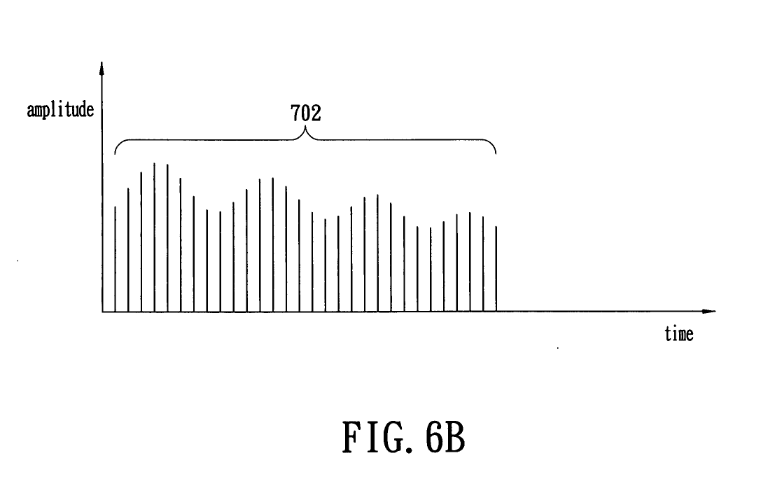

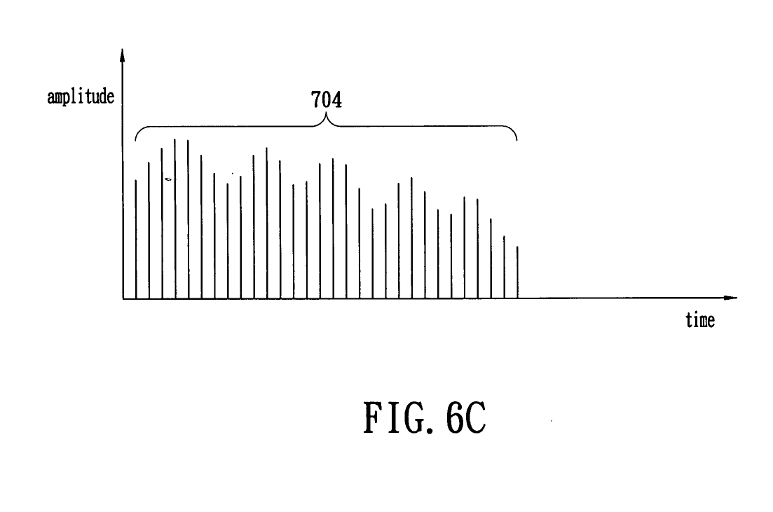

Reference is made to FIG. 6A, which shows the amplitude of the reverberation signal 700 is decreased with time. However, after decorrelation (the reverberation signals of the left and right sounds are decorrelated via random process), the correlation of the reverberation signals of the left and right sounds will be lowered.

Reference is made to FIGS. 6B and 6C, which illustrate the decorrelated reverberation signals 702 and 704 of the left and right sounds. As shown in the two figures, after decorrelation via random process, the correlation of the reverberation signals of the left and right sounds is lowered because their phases are disarranged. Hence, this method can achieve the goal of the decorrelation process and produce the extensity of sounds.

Since the present invention has a parallel structure, the direct and reflected sounds can be separately processed to reduce the complexity considerably and the flexibility for adjusting and controlling the sound channels can be maintained. Further, the calculating complexity does not increase linearly as the number of the input sound channels increases. Additionally, no matter how many sound channels are input, they still use common reverberation generators. Hence, the structure of the stereo generating apparatus can be simplified considerably.

Furthermore, since the direct and reflected sounds are processed separately, the methods for them can be designed individually according to the situation of a site or the required effect. Hence, the feeling of space and distance can be controlled more easily than before, because the left and right space processors can be used to adjust the ratio and time difference of the direct sound and reverberation.

Another feature of the present invention is that the reverberation generators for left and right ears are different. Hence, the correlation between the reverberation signals for the left and right ears can be reduced considerably and the extensity of the reverberation can become broader.

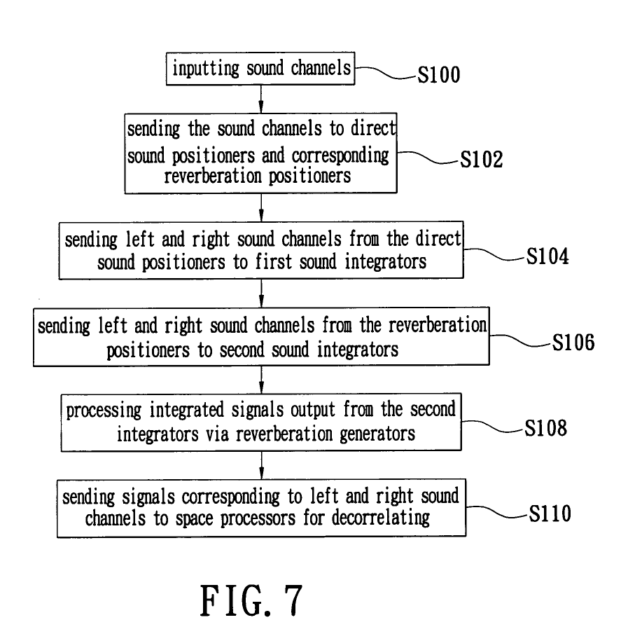

Reference is made to FIG. 7, which is a flowchart of the present invention. First, multiple sound channels are input (S100). Each of the sound channels is sent to a corresponding direct sound positioner and a corresponding reverberation positioner (S102). A left sound channel and a right sound channel output are sent from the direct sound positioner to a first left sound integrator and a first right sound integrator, respectively (S104). A left sound channel and a right sound channel output are sent from the reverberation positioner to a second left sound integrator and a second right sound integrator, respectively (S106). Integrated signals output from the second left sound integrator and second right sound integrator are processed via a left reverberation generator and a right reverberation generator, respectively (S108). An integrated signal output from the first left sound integrator and an generated signal output from the left reverberation generator are sent to a first space processor. An integrated signal output from the first right sound integrator and an generated signal output from the right reverberation generator are sent to a second space processor. The correlation between the first and second space processors is very low (S110).

Although the present invention has been described with reference to the preferred embodiment thereof, it will be understood that the invention is not limited to the details thereof. Various substitutions and modifications have been suggested in the foregoing description, and other will occur to those of ordinary skill in the art. For example, when applied to music with a single sound channel, only a set of the components mentioned above, including a direct sound positioner, a reverberation positioner, a reverberation generator and a space processor, is needed to achieve stereo effects. Therefore, all such substitutions and modifications are embraced within the scope of the invention as defined in the appended claims.

1. An apparatus for generating a stereo sound, comprising:
at least a direct sound positioner used to generate at least a direct sound signal after receiving an input sound channel;
at least a reverberation positioner used to generate at least a reverberation direction signal after receiving the input sound channel;
at least a first sound integrator used to receive the direct sound signal and output an integrated direct sound signal;
at least a second sound integrator used to receive the reverberation direction signal and output an integrated reverberation direction signal;
at least a reverberation generator used to receive the integrated reverberation direction signal and output a reverberation signal; and
at least a space processor used to receive the integrated direct sound signal and the reverberation signal and output the stereo sound for a user.

2. The apparatus as claimed in claim 1, wherein the direct sound signal generated by the direct sound positioner is a right direct sound signal or a left direct sound signal.

3. The apparatus as claimed in claim 1, wherein the reverberation direction signal generated by the reverberation positioner is a right reverberation direction signal or a left reverberation direction signal.

4. The apparatus as claimed in claim 2, wherein the first sound integrator is a left sound integrator used to receive the left direct sound signal generated by the direct sound positioner to output an integrated sound signal, the integrated sound signal being an integrated left direct sound signal.

5. The apparatus as claimed in claim 2, wherein the first sound integrator is a right sound integrator used to receive the right direct sound signal generated by the direct sound positioner to output an integrated sound signal, the integrated sound signal being an integrated right direct sound signal.

6. The apparatus as claimed in claim 3, wherein the second sound integrator is a left sound integrator used to receive the left reverberation direction signal generated by the reverberation positioner to output an integrated sound signal, the integrated sound signal being an integrated left reverberation direction signal.

7. The apparatus as claimed in claim 3, wherein the second sound integrator is a right sound integrator used to receive the right reverberation direction signal generated by the reverberation positioner to output an integrated sound signal, the integrated sound signal being an integrated right reverberation direction signal.

8. The apparatus as claimed in claim 6, wherein the reverberation generator is a left reverberation generator, which uses a finite impulse response (FIR) filter to process the integrated left reverberation direction signal.

9. The apparatus as claimed in claim 7, wherein the reverberation generator is a right reverberation generator, and the right reverberation generator uses a FIR filter to process the integrated right reverberation direction signal.

10. The apparatus as claimed in claim 1, wherein the space processor is used to perform a timing control and adjust a mixed volume of the signals output from the sound integrators.

11. The apparatus as claimed in claim 8, wherein the left reverberation generator is a first filter correlating very little with a right reverberation generator, the right reverberation generator being a second filter.

12. A method for generating a stereo sound, comprising:
using at least a direct sound positioner to generate at least a direct sound signal after receiving an input sound channel;
using at least a reverberation positioner to generate at least a reverberation direction signal after receiving the input sound channel;
using at least a first sound integrator to receive the direct sound signal and output an integrated direct sound signal;
using at least a second sound integrator to receive the reverberation direction signal and output an integrated reverberation direction signal;
using at least a reverberation generator to receive the integrated reverberation direction signal and output a reverberation signal; and
using at least a space processor to receive the integrated direct sound signal and the reverberation signal and output stereo sound for a user.

13. The method as claimed in claim 12, wherein the direct sound signal generated by the direct sound positioner is a right direct sound signal or a left direct sound signal.

14. The method as claimed in claim 12, wherein the reverberation direction signal generated by the reverberation positioner is a right reverberation direction signal or a left reverberation direction signal.

15. The method as claimed in claim 13, wherein the first sound integrator is a left sound integrator used to receive the left direct sound signal generated by the direct sound positioner to output an integrated sound signal, the integrated sound signal being an integrated left direct sound signal.

16. The method as claimed in claim 13, wherein the first sound integrator is a right sound integrator used to receive the right direct sound signal generated by the direct sound positioner to output an integrated sound signal, the integrated sound signal being an integrated right direct sound signal.

17. The method as claimed in claim 14, wherein the second sound integrator is a left sound integrator used to receive the left reverberation direction signal generated by the reverberation positioner to output an integrated sound signal, the integrated sound signal being an integrated left reverberation direction signal.

18. The method as claimed in claim 14, wherein the second sound integrator is a right sound integrator used to receive the right reverberation direction signal generated by the reverberation positioner to output an integrated sound signal, the integrated sound signal being an integrated right reverberation direction signal.

19. The method as claimed in claim 17, wherein the reverberation generator is a left reverberation generator, which uses a FIR filter to process the integrated left reverberation direction signal.

20. The method as claimed in claim 18, wherein the reverberation generator is a right reverberation generator, and the right reverberation generator uses a FIR filter to process the integrated right reverberation direction signal.

21. The method as claimed in claim 12, wherein the space processor is used to perform a timing control and adjust a mixed volume of the signals output from the sound integrators.

22. The method as claimed in claim 19, wherein the left reverberation generator is a first filter correlating very little with a right reverberation generator, and the right reverberation generator is a second filter.

23. A method for generating a stereo sound, used to integrate a plurality of sound channel into a stereo sound channel, the method comprising:
sending each of the sound channels to a corresponding direct sound positioner and a corresponding reverberation;
sending a left sound channel and a right sound channel output from the direct sound positioner to a first left sound integrator and a first right sound integrator, respectively;
sending a left sound channel and a right sound channel output from the reverberation positioner to a second left sound integrator and a second right sound integrator, respectively;
processing integrated signals output from the second left sound integrator and second right sound integrator via a left reverberation generator and a right reverberation generator, respectively;
sending an integrated signal output from the first left sound integrator and a generated signal output from the left reverberation generator to a first space processor for processing; and
sending an integrated signal output from the first right sound integrator and an generated signal output from the right reverberation generator to a second space processor for processing.

24. The method as claimed in claim 23, wherein the left or right reverberation generator is composed of an FIR filter.

25. The method as claimed in claim 23, wherein the left reverberation generator is a first filter and the right reverberation generator is a second filter, and the correlation between the first and second filters is low.
